(19) United States
(12) Patent Application Publication
(10) Pub. No.: US 2010/0068409 A1
(43) Pub. Date: Mar. 18, 2010

(54) INK JET PRINTABLE COMPOSITIONS

(75) Inventors: Arkady Garbar, Yoqneam Illit (IL); Dmitry Lekhtman, Nazaret-Illit (IL); Fernando De La Vega, Zichron Yacov (IL); Shlomo Magdassi, Jerusalem (IL); Alexander Kamyshny, Jerusalem (IL); Frigita Kahana, (US)

Correspondence Address: FISH & RICHARDSON P.C., PO BOX 1022, MINNEAPOLIS, MN, 55440-1022, US

(73) Assignees: Cima NanoTech Israel, Ltd; Yissum Research Development Company

(21) Appl. No.: 12/418,016

(22) Filed: Apr. 3, 2009

Related U.S. Application Data
(63) Continuation of application No. 11/575,281, filed on Oct. 31, 2007, now abandoned.
(60) Provisional application No. 60/609,750, filed on Sep. 14, 2004.

(51) Int. Cl. C09D 11/00; B05D 5/00; H05K 3/00; B05D 3/06

(52) U.S. Cl. 427/532; 106/31.13; 427/256; 427/288; 427/98.4

(57) ABSTRACT

In jet printable compositions that include nano metal powders in a liquid carrier.

### CLAIM OF PRIORITY

This application is a continuation of and claims the benefit of priority under 35 USC §120 to U.S. application Ser. No. 11/575,281, filed on Oct. 31, 2007, which is a National Stage application under 35 U.S.C. §371 and claims benefit under 35 U.S.C. §119(a) of International Application No. PCT/IB2005/002721 having an International Filing Date of Sep. 12, 2005, which claims the benefit of priority of U.S. Provisional application 60/609,750 having a filing date of Sep. 14, 2004. the entire contents of which are hereby incorporated by reference.

### TECHNICAL FIELD

This invention relates to ink jet printable compositions.

### BACKGROUND

Ink jet printing is a widely used printing technique. Specific examples include continuous ink jet printing and drop on demand ink jet printing.

### SUMMARY

We have developed compositions that can be ink jetted to form conductive patterns on a variety of substrates. Dispersions hereby are nano metal powders dispersed in a liquid carrier. Inks are dispersions with additional additives to impart additional properties to the dispersion in order to fulfill requirements of the printing process and the final product properties. The final printed product is in the form of a conductive pattern that may have additional properties depending on its specific application. The nano metal powders, which are produced by the Metallurgic Chemical Process (MCP) process described herein, have special properties, enabling the dispersion and de-agglomeration of the powder in a liquid carrier (organic solvent, water, or any combination thereof), with or without additives. Taking advantage of these attributes we have been able, with the MCP-produced nano metal powders, to design compositions with very low viscosities, as required for ink jet printing at high metal concentrations, by selecting appropriate combinations of the nano metal powder, liquid carrier, and, optionally, additives. The ability to combine high metal concentrations with very low viscosities makes the compositions particularly useful for ink jet printing.

Dispersions comprising nano metal particles dispersed substantially homogeneously in a liquid carrier that includes (a) water, a water-miscible organic solvent, or combination thereof or (b) an organic solvent, or combination of organic solvents and (c) surfactants, wetting agents, stabilizers, humectants, rheological agents, and combinations thereof, are described.

Inks based upon these dispersions, and further including property-modifying additives (e.g. adhesion promoters, rheology adjusting additives, and the like) are also described.

The compositions have properties that enable their jettability (printing through ink jet print heads which posses small nozzles, usually in the micron range). These properties include the following: low viscosities between 1 and 200 cP (at room temperature or at jetting temperature), surface tension between 20-37 dyne/cm for solvent based dispersions and 30-60 dyne/cm for water based dispersions, metal loadings of nano particles between 1% and 70% (weight by weight), low particle size distribution of the nano metal particle material having a particle size distribution (PSD) D90 below 150 nm, preferably below 80 nm. The compositions have stabilities sufficient to enable jetting with minimum settling, and without clogging the print head or changing the properties of the compositions. The compositions can be printed by different technologies including continuous ink jet technologies, drop on demand ink jet technologies (such as piezo and thermal) and also additional techniques like air brush, flexo, electrostatic deposition, wax hot melt, etc.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a representative ink jet printed pattern.

FIGS. 2-6 are Scanning Electron Microscopy (SEM) photographs of nano metal particles used to prepare the ink jettable compositions.

FIGS. 7-8 are Transmission Electron Microscopy (TEM) photographs of ink jettable compositions.

FIG. 9 is an x-ray diffraction scan of nano metal particles used to prepare ink jettable compositions.

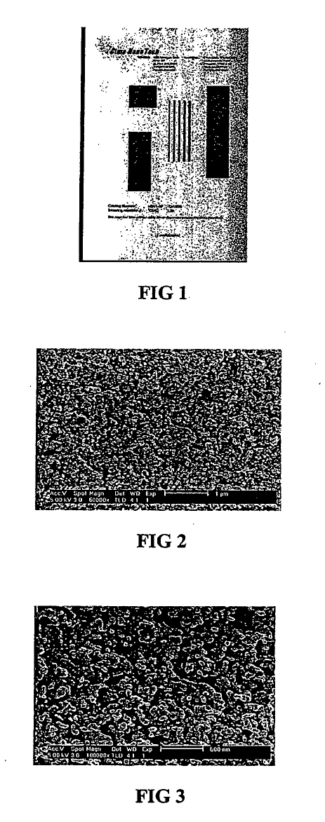

Like reference symbols in the various drawings indicate like elements.

### DETAILED DESCRIPTION

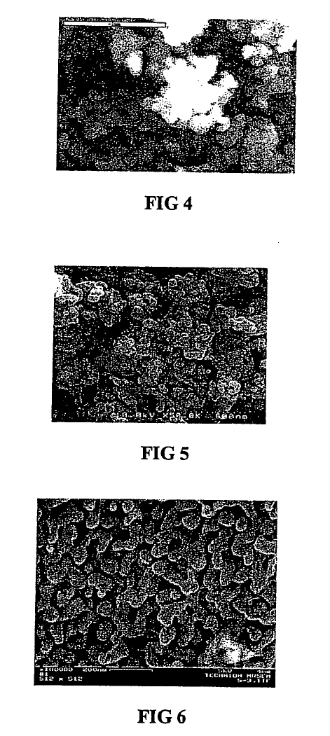

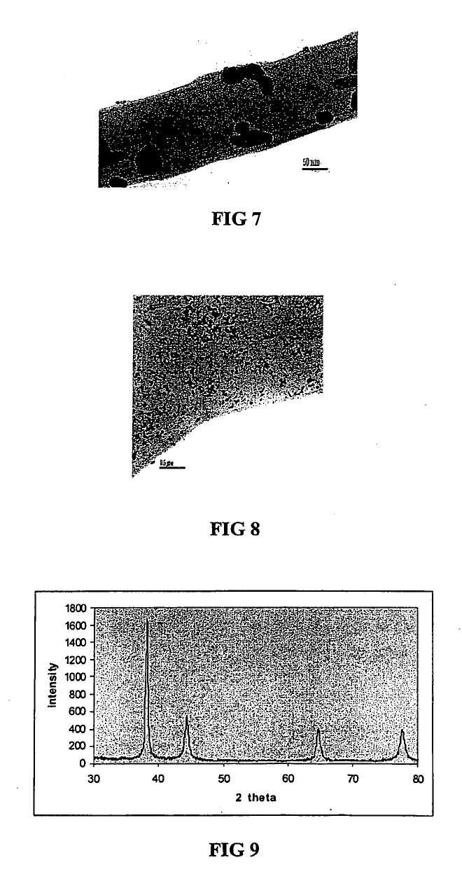

The ink jettable compositions feature nano metal particles in a liquid carrier. Suitable nano metal particles include silver, silver-copper alloys, silver-palladium alloys, and other metals and metal alloys produced by the process described in U.S. Pat. No. 5,476,535 (“Method of producing high purity ultra-fine metal powder”) and PCT application WO 2004/000491 A2 (“A Method for the Production of Highly Pure Metallic Nano-Powders and Nano-Powders Produced Thereof”), both of which are hereby incorporated by reference in their entirety. The nano metal particles have a “non uniform spherical” shape and their chemical compositions include aluminum up to 0.4% (weight by weight), both of which are unique to this production method. SEM photographs of representative nano metal particles are shown in FIGS. 2-6. TEM photographs of a representative composition prepared by dispersing nano metal particles in a liquid carrier are shown in FIGS. 7-8. The non-uniform (deformed ellipsoidal) shape of the particles is evident from the XRD data shown in FIG. 9 and from particle size distribution measurements.

Useful liquid carriers include water, organic solvents, and combinations thereof. Useful additives include surfactants, wetting agents, stabilizers, humectants, rheology adjusting agents, adhesion promoters, and the like. Specific examples, many of which are commercially available, include the following:
Organic solvents: DPM (di(propyleneglycol)methyl ether), PMA (1,2-propanediol monomethyl ether acetate), Dowanol DB (diethylene glycol monobutyl ether), BEA (butoxyethyl acetate).
Dispersing agents and stabilizers for solvent-based dispersions: BYK-9077, Disperbyk-163, PVP K-15.
Dispersing/wetting agents and stabilizers for water-based dispersions: BYK-154, BYK-162, BYK-180, BYK-181, BYK-190, BYK-192, BYK-333, BYK-348, Tamol T1124, SDS, AOT, Tween 20, Tween 80, L-77, Betaine, Sodium Laureth Sulfosuccianate and Sulfate, Tego 735W, Tego 740W, Tego 750W, Disperbyk, PDAC (poly(diallyldimethylammonium chloride)), Nonidet, CTAC, Daxad 17 and 19 (sodium salt of naphthalene sulfonate formaldehyde condensate), BASF 104, Solspers 43000, Solspers 44000, Atlox 4913, PVP K-30, PVP K-15, Joncryl 537, Joncryl 8003, Ufoxan, STPP, CMC, Morwet, LABS W-100A, Tamol 1124.
Humectants for water-based dispersions: PMA, DPM, glycerol, Sulfolam, diethylene glycol, triethanolamine, Dowanol DB, ethanol, DMF (dimethyl formamide), isopropanol, n-propanol, PM (1-methoxy-2-propanol), Diglyme (di(ethylene glycol) diethyl ether), NMP (1-methyl pyrrolidinone).

The printed patterns produced hereby can be treated post printing in any suitable way to increase their conductivity. The treatments may be any of the following methods or combinations thereof: methods described in PCT applications WO 2004/005413 A1 (“Low Sintering Temperatures Conductive Inks—a Nano Technology Method for Producing Same”) and WO03/106573 (“A Method for the Production of Conductive and Transparent Nano-Coatings and Nano-Inks and Nano-Powder Coatings and Inks Produced Thereby”), application of radiation, microwave, light, flash light, laser sintering, applying pressure, rubbing, friction sintering, thermal heat (applied in any form, e.g. forced air oven, hot plate, etc), continuous radiation, scanned beam, pulsed beam, etc. Preferably the treatment is a “chemical sintering method” (CSM) described in a provisional patent application No. ______ entitled “Low Temperature Sintering Process for Preparing Conductive Printed Patterns on Substrates, and Articles Based Thereon” filed concurrently with the present application, and in WO 03/106573.

The dispersions and inks may be printed onto a wide range of surfaces, including flexible, rigid, elastic, and ceramic surfaces. Specific examples include paper, polymer films, textiles, plastics, glass, fabrics, printed circuit boards, epoxy resins, and the like.

The invention will now be described further by way of the following examples.

### EXAMPLES

### Example 1

A dispersion of 30% by weight of silver nano powder (#471-G51) (prepared as described in U.S. Pat. No. 5,476,535 and PCT application WO 2004/000491 A2), 0.7% Disperbyk® 348 (available from BYK-Chemie, Wesel Germany), 5.3% BYK® 190 (also available from BYK-Chemie), 0.35% PVP K-30 (available from Alfa Aesar—Johnson Matthey), 3.15% DPM (Dipropylene glycol methyl ether), 25.5% iso-propanol (IPA), and the balance water was prepared by mixing the additives with the solvents and water, then adding the silver nano powder in portions while mixing with a high speed homogenizer Dispermat (VMA-GETZMANN GMBH) at 4000 rpm with a 47 mm diameter dissolver shaft, until the minimum particle size distribution (PSD) was achieved. Typically, homogenization was performed for 10 min at 6000 rpm. The dispersion was printed in a Hewlett-Packard Deskjet 690 printer.

### Example 2

A dispersion of 40% by weight of silver nano powder (#471-W51) (prepared as described in Example 28), 0.6% Disperbyk® 348 (available from BYK-Chemie, Wesel Germany), 4.6% BYK® 190 (also available from BYK-Chemie), 0.1% PVP K-30 (available from Alfa Aesar—Johnson Matthey), 11% NMP, 0.5% AMP, and the balance water was prepared by mixing the additives with the solvents and water, then adding the silver nano powder in portions while mixing with a high speed homogenizer Dispermat (VMA-GETZMANN GMBH) at 4000 rpm with a 47 mm diameter dissolver shaft, until the minimum PSD was achieved. Typically, homogenization was performed for 10 min at 6000 rpm. The dispersion was printed in a Hewlett-Packard Deskjet 690 printer.

### Example 3

A dispersion of 50% by weight of silver nano powder (#471-G51) (prepared as described in U.S. Pat. No. 5,476,535 and PCT application WO 2004/000491 A2), 0.5% Disperbyk® 348 (available from BYK-Chemie, Wesel Germany), 3.8% BYK® 190 (also available from BYK-Chemie), 0.25% PVP K-30 (available from Alfa Aesar—Johnson Matthey), 0.25% Tween 20 (available from Aldrich), 9.1% NMP, and the balance water was prepared by mixing the additives with the solvents and water, then adding the silver nano powder in portions while mixing with a high speed homogenizer Dispermat (VMA-GETZMANN GMBH) at 4000 rpm with a 47 mm diameter dissolver shaft, until the minimum PSD was achieved. Typically, homogenization was performed for 10 min at 6000 rpm. The dispersion was printed in a Hewlett-Packard Deskjet 690 printer.

### Example 4

A dispersion of 60% by weight of silver nano powder (#471-G51) (prepared as described in U.S. Pat. No. 5,476,535 and PCT application WO 2004/000491 A2), 0.4% Disperbyk® 348 (available from BYK-Chemie, Wesel Germany), 3% BYK® 190 (also available from BYK-Chemie), 0.1% PVP K-30 (available from Alfa Aesar Johnson Matthey), 7.3% NMP, 0.4% AMP, and the balance water was prepared by mixing the additives with the solvents and water, then adding the silver nano powder in portions while mixing with a high speed homogenizer Dispermat (VMA-GETZMANN GMBH) at 4000 rpm with a 47 mm diameter dissolver shaft, until the minimum PSD was achieved. The dispersion was printed in a Hewlett-Packard Deskjet 690 printer.

### Example 5

A dispersion of 60% by weight of silver nano powder (#473-G51) (prepared as described in Example 26), 0.4% Disperbyk® 348 (available from BYK-Chemie, Wesel Germany), 3% BYK® 190 (also available from BYK-Chemie), 0.1% PVP K-30 (available from Alfa Aesar—Johnson Matthey), 0.4% AMP, 7.3% iso-propanol (IPA), and the balance water was prepared by mixing the additives with the solvents and water, then adding the silver nano powder in portions while mixing with a high speed homogenizer Dispermat (VMA-GETZMANN GMBH) at 4000 with a 47 mm diameter dissolver shaft, until the minimum PSD was achieved. Typically, homogenization was performed for 10 min. The dispersion was printed in a Hewlett-Packard Deskjet 690 printer.

### Example 6

A dispersion of 60% by weight of silver nano powder (#473-W51) (prepared as described in U.S. Pat. No. 5,476,535 and PCT application WO 2004/000491 A2), 0.4% Disperbyk® 348 (available from BYK-Chemie, Wesel Germany), 3% BYK® 190 (also available from BYK-Chemie), 0.1% PVP K-30 (available from Alfa Aesar—Johnson Matthey), 0.4% AMP, 11% NMP, and the balance water was prepared by mixing the additives with the solvents and water, then adding the silver powder in portions while mixing with a high speed homogenizer Dispermat (VMA-GETZMANN GMBH) with a 47 mm diameter dissolver shaft, until the minimum PSD was achieved. Typically, homogenization was performed for 10 min at 6000 rpm. The dispersion was printed in a Hewlett-Packard Deskjet 690 printer.

### Example 7

A dispersion of 10% by weight of silver nano powder (#471-W51) (prepared as described in Example 28), 0.5% Disperbyk® 163 (available from BYK-Chemie, Wesel Germany), 0.007% BYK® 333 (also available from BYK-Chemie), and the balance BEA (Buthoxy ethylacetate) was prepared by mixing the additives with the solvents, then adding the silver nanopowder in portions while mixing with a high speed homogenizer Dispermat (VMA-GETZMANN GMBH) at 4000 rpm with a 47 mm diameter dissolver shaft, until the minimum PSD was achieved (D100 76 nm). Typically, homogenization was performed for 10 min at 6000 rpm. A surface tension of 26 mN/m was measured according to the Dunoy ring method.

### Example 8

A dispersion of 60% by weight of silver nano powder (#473-G51) (prepared as described in Example 26), 3% Disperbyk® 163 (available from BYK-Chemie, Wesel Germany), 0.04% BYK® 333 (also available from BYK-Chemie), and the balance BEA (Buthoxy ethylacetate) was prepared by mixing the additives with the solvents, then adding the silver nano powder in portions while mixing with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 17 cP using a Brookfield Viscometer. A surface tension of 26.5 mN/m was measured using the Dunoy ring method. A conductive pattern prepared using the composition was sintered at 300° C. for 30 minutes, after which the resistivity was measured and determined to be 5 μΩ cm.

### Example 9

A dispersion of 10% by weight of silver nano powder (#473-G51) (prepared as described in Example 26), 0.6% Disperbyk® 190 (available from BYK-Chemie, Wesel Germany), 0.015% BYK® 348 (also available from BYK-Chemie), 0.015% PVP K-30 (available from Alfa Aesar—Johnson Matthey), 0.93% NH₃ water solution, 18.66% NMP, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 76 nm). Typically, homogenization was performed for 10 min at 6000 rpm. The viscosity of the composition was determined to be 4 cP using a Brookfield Viscometer. A surface tension of 47.5 mN/m was measured using the Dunoy ring method.

### Example 10

A dispersion of 40% by weight of silver nano powder (#473-G51) (prepared as described in Example 26), 2.4% Disperbyk® 190 (available from BYK-Chemie, Wesel Germany), 0.06% BYK® 348 (also available from BYK-Chemie), 0.06% PVP K-30 (available from Alfa Aesar—Johnson Matthey), 0.6% NH₃ water solution, 12% NMP, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 17 cP using a Brookfield Viscometer. A surface tension of 47.5 mN/m was measured using the Dunoy ring method.

### Example 11

A dispersion of 60% by weight of silver nano powder (#473-G51) (prepared as described in Example 26), 3% Disperbyk® 190 (available from BYK-Chemie, Wesel Germany), 0.08% BYK® 348 (also available from BYK-Chemie), 0.2% PVP K-15 (available from Fluka), 0.147% AMP (2-amino-2-methyl-propanol), 7.343% NMP (1-methylpyrrolidinone), and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 15 cP using a Brookfield Viscometer. A surface tension of 47.5 mN/m was measured using the Dunoy ring method.

### Example 12

A dispersion of 10% by weight of silver nano powder (#471-W51) (prepared as described in Example 28), 1.14% Disperbyk® 190 (available from BYK-Chemie, Wesel Germany), 0.15% Tween 20 (available from Aldrich), 0.15% NH₃ water solution, 1.5% PMA, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D50 50 nm). Typically, homogenization was performed for 10 min at 6000 rpm. The viscosity of the composition was determined to be 3 cP using a Brookfield Viscometer. A conductive pattern prepared using the composition was sintered at 300° C. for 30 minutes, after which its resistivity was measured and determined to be 11 μΩ cm.

### Example 13

A dispersion of 60% by weight of silver nano powder (#471-W51) (prepared as described in Example 28), 3% Disperbyk® 190 (available from BYK-Chemie, Wesel Germany), 0.08% BYK® 348 (also available from BYK-Chemie), 0.2% PVP K-30 (available from Alfa Aesar—Johnson Matthey), 0.147% AMP, 7.343% NMP, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D50 50 nm). Typically, homogenization was performed for 10 min. The viscosity of the composition was determined to be 18 cP using a Brookfield Viscometer. A conductive pattern prepared using the composition was sintered at 300° C. for 30 minutes, after which its resistivity was measured and determined to be 11 μΩ cm.

### Example 14

A dispersion of 50% by weight of silver nano powder (#471-W51) (prepared as described in Example 28, 0.3% Disperbyk® 348 (available from BYK-Chemie, Wesel Germany), 0.5% NH₃ water solution, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved. Typically, homogenization was performed for 10 min at 6000 rpm. A conductive pattern prepared using the composition was sintered at 300° C. for 30 minutes, after which its resistivity was measured and determined to be 19 μΩ cm.

### Example 15

A dispersion of 20% by weight of silver nano powder (#473-G51) (prepared as described in Example 26), 1% Disperbyk® 190 (available from BYK-Chemie, Wesel Germany), 0.027% BYK® 348 (also available from BYK-Chemie), 0.067% PVP K-15 (available from Fluka), 0.313% AMP (2-amino-2-methyl-propanol), 15.76% NMP (1-methylpyrrolidinone), and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min. The viscosity of the composition was determined to bet 15 cP using a Brookfield Viscometer. A surface tension of 47.5 mN/m was measured using the Dunoy ring method. A conductive pattern was printed with this dispersion using a Lexmark printer Z602, cartridge Lexmark Black 17 and 16 in which the black ink had been replaced with this dispersion. The dispersion was printed on HP photoquality paper semi-glossy (C6984A). Two passes were performed. The conductive pattern was sintered at 150° C. for 90 minutes, after which its resistivity was measured and determined to be 70 μΩ cm.

### Example 16

The procedure of Example 15 was followed except that the dispersion was printed on Epson premium Glossy Photo paper (S0412870). The conductive pattern was sintered at 80° C. for 30 minutes, after which its resistivity was measured and determined to be 70 μΩ cm.

### Example 17

The procedure of Example 15 was followed except that the composition was printed on an HP Premium Inkjet Transparency Film (C3835A). The conductive pattern was sintered at 150° C. for 30 minutes, after which its resistivity was measured and determined to be 70 μΩ cm.

### Example 18

A dispersion of 20% by weight of silver palladium nano powder (#455) (prepared as described in U.S. Pat. No. 5,476,535 and PCT application WO 2004/000491 A2), 4% Disperbyk® 163 (available from BYK-Chemie, Wesel Germany), and the balance BEA was prepared by mixing the additives with the solvent, then adding the silver palladium nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D50 50 nm). Typically, homogenization was performed for 10 min. The viscosity of the composition was determined to be 3 cP using a Brookfield Viscometer. A conductive pattern prepared using the composition was sintered at 300° C. for 30 minutes, after which its resistivity was measured and determined to be 113 μΩ cm.

### Example 19

A dispersion of 40% by weight of silver nano powder (#471-W51) (prepared as described in Example 28), 0.3% BYK® 348 (available from BYK-Chemie, Wesel Germany), 0.6% NH₃ water solution, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 20 cP using a Brookfield Viscometer with a constant shear cone spindle #4 at 200 rpm. A surface tension of 47.5 mN/m was measured using the Dunoy ring method. A conductive pattern prepared using the composition was sintered at 300° C. for 30 minutes, after which its resistivity was measured and determined to be 17 μΩ cm.

### Example 20

A dispersion of 60% by weight of silver nano powder (#471-W51) (prepared as described in Example 28), 0.3% BYK® 348 (available from BYK-Chemie, Wesel Germany), 0.4% NH₃ water solution, and the balance water was prepared by mixing the additives with the solvents and water, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 78 cP using a Brookfield Viscometer with a constant shear cone, spindle #4 at 200 rpm. A surface tension of 47.5 mN/m was measured using the Dunoy ring method. A conductive pattern prepared using the composition was sintered at 300° C. for 30 minutes, after which its resistivity was measured and determined to be 24 μΩ cm.

### Example 21

A dispersion of 40% by weight of silver nano powder (#471-W51) (prepared as described in Example 28), 0.3% BYK® 348 (available from BYK-Chemie, Wesel Germany), 0.6% NH₃ water solution, and the balance water was prepared by mixing the additives with the solvents and water, then adding the silver powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 20 cP using a Brookfield Viscometer with a constant shear cone spindle #4 at 200 rpm. A surface tension of 47.5 mN/m was measured using the Dunoy ring method. A conductive pattern prepared using the composition was sintered at 300° C. for 30 minutes, after which its resistivity was measured and determined to be 17 μΩ cm.

### Example 22

A dispersion of 40% by weight of silver nano powder (#471-W51) (prepared as described in Example 28), 2% BYK® 9077 (available from BYK-Chemie, Wesel Germany), and the balance PMA was prepared by mixing the additive with the solvent, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 20 cP using a Brookfield Viscometer with a constant shear cone spindle #4 at 200 rpm. A conductive pattern prepared using the composition was sintered at 300° C. for 30 minutes, after which its resistivity was measured and determined to be 17 μΩ cm.

### Example 23

A dispersion of 50% by weight of silver nano powder (#471-W51) (prepared as described in Example 28), 2.5% BYK® 9077 (available from BYK-Chemie, Wesel Germany), and the balance PMA was prepared by mixing the additive with the solvent, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 24 cP using a Brookfield Viscometer with a constant shear cone spindle #4 at 200 rpm. A conductive pattern prepared using the composition was sintered at 300° C. for 30 minutes, after which its resistivity was measured and determined to be 14 μΩ cm.

### Example 24

A dispersion of 60% by weight of silver nano powder (#471-W51) (prepared as described in Example 28), 3% BYK® 9077 (available from BYK-Chemie, Wesel Germany), and the balance PMA was prepared by mixing the additive with the solvent, then adding the silver nano powder in portions while mixing at 4000 rpm with a high speed Premier Mill Laboratory Dispersator Series 2000 Model 90 (Premier Mill Corp. USA) having a 47 mm diameter dissolver shaft, until the minimum PSD was achieved (D100 77 nm). Typically, homogenization was performed for 10 min at 6000 rpm. The viscosity of the composition was determined to be 40 cP using a Brookfield Viscometer with a constant shear cone spindle #4 at 200 rpm. A conductive pattern prepared using the composition was sintered at 300° C. for 30 minutes, after which its resistivity was measured and determined to be 14 μΩ cm.

Examples 25-28 describe the preparation of various nano metal powders.

### Example 25

### Nano Powder Production Through MCP Process #440

Silver nano powder was prepared by making a melt of 30% by weight of silver and 70% aluminum (e.g., 300 grams silver and 700 grams aluminum) in a stirred graphite crucible in an induction melting furnace under air at a temperature of at least 661° C. The melt was poured into a 14 mm thick mold made from steel. The molded ingot was left to cool at room temperature, and then annealed in an electrical furnace at 400° C. for 2 hours. The annealed ingot was left to cool at room temperature, then rolled at room temperature in a rolling machine (from 13 mm thickness to 1 mm thickness in 22 passes). The sheets were cut and heat treated in an electrical furnace at 560° C. for 4 hours. The heated sheets were quenched in water at room temperature. The sheets were then leached in an excess of a NaOH solution (25% by weight in deionized water—density 1.28 grams/ml at room temperature, 1.92 kg NaOH solution per 0.1 kg alloy) at a starting temperature of 28° C. and while cooling to keep temperature below 70° C. for 12 hours (leaching reactor without external agitation).

Next, the NaOH solution was decanted and a new portion of 25% NaOH solution was added (40 gram per 0.1 kg starting alloy), after which the sample was left for 2 hours. The slurry was filtered and washed with deionized water to a pH of 7. The powder was then dried in an air convection oven at a temperature below 45° C. The powder produced at this stage had a prime particle size below 80 nm, as measured by XRD and SEM, and a typical chemical composition of 99.7% silver, 0.3% aluminum, and traces of sodium, iron, copper and other impurities.

An ethanol solution was prepared by dissolving 15.66 grams Span 20 and 2.35 grams hexadecanol in 750 ml ethanol. 500 grams of leached dry powder was added to the ethanolic solution and stirred for 2 hours. The slurry was poured into a tray and the ethanol evaporated at temperature below 45° C. The coated powder was then passed through a jet mill to get a de-agglomerated silver nano powder with particle size (D90) below 80 nm, as measured by laser diffraction.

### Example 26

### Nano Powder Production Through MCP Process #473-G51

Silver nano powder was prepared by making a melt of 24.4% by weight of silver, 0.6% by weight copper and 75% aluminum (e.g., 243.8 grams silver, 6.3 gram copper and 750 grams aluminum) in a stirred graphite crucible under air at a temperature of at least 661° C. The melt was poured into a 14 mm thick mold made from steel. The molded ingot was left to cool at room temperature, and then annealed in an electrical furnace at 400° C. for 2 hours. The annealed ingot was left to cool at room temperature, and then rolled at room temperature in a rolling machine (from 13 mm thickness to 1 mm thickness in 24 passes). The sheets were cut and heat treated in in an electrical furnace at 440° C. for 4 hours. The heated sheets were quenched in water at room temperature. The sheets were then leached in an excess of a NaOH solution (25% by weight in deionized water—density 1.28 grams/ml at room temperature, 1.92 kg NaOH solution per 0.1 kg alloy) at a starting temperature of 28° C. and while cooling to keep the temperature below 70° C. for 12 hours (leaching reactor without external agitation).

The NaOH solution was then decanted and a new portion of 25% NaOH solution was added (40 gram per 0.1 kg starting alloy) and left for 2 hours. The powder produced at this stage had a prime particle size below 80 nm, as measured by XRD and SEM, and a surface area greater than 5 mt²/gram. An ethanol solution was prepared by dissolving 15.66 grams Span 20 and 2.35 grams hexadecanol in 750 ml ethanol. 500 grams of leached dry powder was added to the ethanolic solution and stirred for 2 hours. The slurry was poured into a tray and the ethanol evaporated at a temperature below 45° C. The coated powder was then passed through a jet mill to get a de-agglomerated silver nano powder with particle size (D90) below 80 nm, as measured by laser diffraction.

The powder produced in the previous steps was further washed with hot ethanol several times (between 3 and 5 times), and then dried in tray until all the ethanol evaporated at a temperature below 45° C. A de-agglomerated silver nano powder with particle size (D90) below 80 nm, as measured by laser diffraction, and organic coating of less than 1.2% by weight, as measured by TGA, was obtained.

### Example 27

### Nano Powder Production Through MCP Process #473-SH

Silver nano powder was prepared by making a melt of 24.4% by weight of silver, 0.6% by weight copper and 75% aluminum (e.g., 243.8 grams silver, 6.3 gram copper and 750 grams aluminum) in a stirred graphite crucible under air at a temperature of at least 661° C. The melt was poured into a 14 mm thick mold made from steel. The molded ingot was left to cool at room temperature, and then annealed in an electrical furnace at 400° C. for 2 hours. The annealed ingot was left to cool at room temperature, ands then rolled at room temperature in a rolling machine (from 13 mm thickness to 1 mm thickness in 24 passes). The sheets were cut and heat treated in in an electrical furnace at 440° C. for 4 hours. The heated sheets were quenched in water at room temperature. The sheets were then leached in an excess of a NaOH solution (25% by weight in deionized water—density 1.28 grams/ml at room temperature, 1.92 kg NaOH solution per 0.1 kg alloy) at a starting temperature of 28°C., while cooling to keep temperature below 70° C., for 12 hours (leaching reactor without external agitation).

The NaOH solution was then decanted and a new portion of 25% NaOH solution was added (40 gram per 0.1 kg starting alloy) and left for 2 hours. The powder produced at this stage had a prime particle size below 80 nm, as measured by XRD and SEM, and surface area greater than 5 mt²/gram. An ethanol solution was prepared by dissolving 15.66 grams Span 20 and 2.35 grams hexadecanol in 750 ml ethanol. 500 grams of leached dry powder was added to the ethanolic solution and stirred for 2 hours. The slurry was poured into a tray and the ethanol evaporated at temperature below 45° C. The coated powder was passed through a jet mill to get a de-agglomerated silver nano powder with particle size (D90) below 80 nm, as measured by laser diffraction.

### Example 28

### Nano Powder Production Through MCP Process #471-W51

Silver nano powder was prepared by making a melt of 10% by weight of silver, 0.1% by weight copper and 89.9% aluminum (e.g., 99 grams silver, 1 gram copper and 899 grams aluminum) in a stirred graphite crucible under air at a temperature of at least 661° C. The melt was poured into a 14 mm thick mold made from steel. The molded ingot was left to cool at room temperature, and then annealed in an electrical furnace at 400° C. for 2 hours. The annealed ingot was left to cool at room temperature, and then rolled at room temperature in a rolling machine (from 13 mm thickness to 1 mm thickness in 24 passes). The sheets were cut and heat treated in in an electrical furnace at 440° C. for 4 hours. The heated sheets were quenched in water at room temperature. The sheets were leached in a NaOH solution (25% by weight in deionized water—density 1.28 grams/ml at room temperature, 1.92 kg NaOH solution per 0.1 kg alloy) at a starting temperature of 28° C. while cooling to keep temperature below 95° C. When the temperature reached 95° C., the solution was allowed to sit for 10 minutes, after which the NaOH solution was decanted (leaching reactor without external agitation). The powder produced at this stage had a prime particle size below 80 nm, as measured by XRD and SEM, and a surface area greater than 11 mt²/gram.

A water solution was prepared by dissolving 13.5 grams Tamol T1124 (available from Rohm & Hass) in 170 ml water. 300 grams of leached dry powder was added to the water solution and stirred for 100 minutes. The slurry was then poured into a tray and the water evaporated at temperature below 45° C. The coated powder was passed through a jet mill to get a de-agglomerated silver nano powder with particle size (D90) below 70 nm, as measured by laser diffraction.

### Example 29

### Stability

The composition prepared in Example 15 was filtered after 14 days through a 5 μm filter. The metal load before and after filtration was 19.7% and 19.6%, respectively, measured by weight using the TGA method. The PSD was also measured and no change found. This indicates that the composition exhibited good stability and dispersability.

### Examples 30-34

Examples 30-34 describe various solvent-based compositions. The constituents and properties of the individual compositions are listed in Table 1. The compositions, each of which included 60% by weight of silver nano powder No. 471-W51 (prepared as described in Example 28), were prepared as follows: 6 g of liquid carrier having the composition set forth in Table 1 was homogenized using a Dispermat (VMA-GETZMANN GMBH) at 4000 rpm. 9 g of silver/copper alloy nano powder was added gradually and then homogenization was performed for 10 min at 6000 rpm. The particle size measurements were measured with the use of HPPS (Malvern Instruments) for dispersions diluted in a liquid similar to that of the dispersion. The measurements were carried out only for liquid-phase dispersions. Some dispersions formed pastes after homogenization; these pastes were not further studied.

TABLE 1
Solvent-based formulations

| | | | | | Surface | | |
|---|---|---|---|---|---|---|---|
| | | Viscosity | Viscosity | | tension of | | Surface tension |
| Example | Formulations | 25° C. | 45° C. | Size | dispersion | Solution | of solution |
| 30 | 60% 471-W51 in (7.6% Byk | 14 cp | 11 cp | 35 nm (9%) | 25.45 (mN/m) | (0.1% Byk 333 + | 24.4 (mN/m) |
| | 9077 in PMA) + 0.1% Byk 333 | | | 235 nm (63%) | | 7.6% Byk 9077) in | |
| | | | | 450 nm (27%) | | PMA | |
| 31 | 60% 471-W51 in (7.6% Byk 163 + | 18 cp | 11.3 cp | 15 nm (20%) | 25.21 (mN/m) | (0.1% Byk 333 + | 24.5 (mN/m) |
| | 0.1% Byk 333) in (Dowanol | | | 230 nm (80%) | | 7.6% Byk 163) in | |
| | DB + 30% PMA) | | | | | (Dowanol DB + | |
| | | | | | | 30% PMA) | |
| 32 | 60% 471-W51 in (7.6% Byk 163 | 7.5 cp | 5.1 cp | 25 nm (75%) | +0.1% Byk 333 | (0.1% Byk 333 + | 25.3 (mN/m) |
| | in BEA) | | | 230 nm (24%) | 26.2 mN/m | 7.6% Byk 163) in | |
| | | | | | | BEA | |
| 33 | 60% Ag (Sp.ol) in (7.6% Byk | 12.4 cp | 8.8 cp | 550 nm (55%) and 1μ | 26.9 mN/m | 7.6% Byk 163 in | 27.1 (mN/m) |
| | 163 in BEA) | | | (44%). Pecipitation in | | BEA | |
| | | | | cuvette during size | | | |
| | | | | measurement | | | |
| 34 | 60% 471-W51 in (7.6% Byk | 16.8 cp | 11.3 cp | 70 nm (8%) | | | |
| | 163 + 0.1% Byk 333 + 0.5% PVP | | | 230 nm (90%) | | | |
| | K-15) in (Dowanol DB + 30% | | | Sometimes small | | | |
| | MPA) | | | peaks at 1μ and 2.7μ | | | |
| | | | | are observed | | | |

As shown in Table 1, formulations composed of Ag/Cu alloy nano powder dispersed in PMA, Dowanol DB plus PMA, or BEA, and containing BYK 9077 or Disperbyk 163 as dispersing agents, and BYK-333 as a wetting agent, are good candidates to be used as ink-jet inks. These formulations are characterized by 2-3 peaks in size distribution graphs (15-35 nm, 230-235 nm, and 450 nm). Viscosity was found to be in the range 14-18 cP at 25° C. and 11 cP at 45° C., surface tension is about 24-25 mN/m. After about 10 days, there was some sedimentation (easily redispersed by shaking), but there was no clear visible separation, which indicates that there were many small particles still dispersed in the liquid.

### Examples 35-43

Examples 35-43 describe various water-based compositions. The constituents and properties of the individual compositions are listed in Table 2. The compositions, each of which included 60% by weight of silver nano powder No. 473-G51 (prepared as described in Example 26), were prepared as follows: 6 g of liquid carrier having the composition set forth in Table 2 was homogenized using a Dispermat (VMA-GETZMANN GMBH) at 4000 rpm. 9 g of silver nano powder was added gradually and then homogenization was performed for 10 min at 6000 rpm. The particle size measurements were measured with the use of HPPS (Malvern Instruments) for dispersions diluted in a liquid similar to that of the dispersion. The measurements were carried out only for liquid-phase dispersions. Some of the dispersions formed pastes after homogenization; these pastes were not further studied.

TABLE 2
Water-based formulations with NanoPowder product 473-G51

| | | | | Rheological | Viscosity | |
|---|---|---|---|---|---|---|
| Example | Sample | Dispersants, wetting agents and solvents | Size by volume distribution | properties | 25° C. | 45° C. |
| 35 | 473-G51 | (0.2% Byk 348 + 7.6% Byk 190 + 0.5% PVP | 20 nm (90%); 230 nm (8%); | Liquid with a | | |
| | | K-30) in [1% AMP in H₂O (pH = 11.5) + 20% NMP] | sometimes small peak at 2.7μ | small amount | | |
| | | | is observed | of precipitate | | |
| 36 | 473-G51 | (0.2% Byk 348 + 7.6% Byk 190 + 0.5% PVP | 16 nm (80%); 230 nm (11%); | Liquid with | | |
| | | K-30) in [1% AMP in H₂O (pH = 11.5) + 10% PMA] | small peaks at 1μ and | precipitate | | |
| | | | 2.7μ are observed | | | |
| 37 | 473-G51 | (0.2% Tween 20 + 7.6% Byk 190 + 0.5% PVP K-30) | 19 nm (30%); 230 nm (7%); | Liquid with | | |
| | | in [1% AMP in H₂O (pH = 11.5) + 10% Dowanol DB] | Sometimes small peaks at 1μ | precipitate | | |
| | | | and are 2.7μ | | | |
| 38 | 473-G51 | (0.2% Byk 348 + 7.6% Daxad 19) in [1% AMP in | | Paste | | |
| | | H₂O (pH = 11.5) + 20% NMP] | | | | |
| 39 | 473-G51 | (0.2% Byk 348 + 7.6% Byk 190 + 0.5% PVP | 20 nm (80%); 230 nm (9%); | Liquid with soft | 27.3 cp | 26 cp |
| | | K-30) in [1% AMP (pH = 11.5) + 20% n-propanol] | small peaks at 1μ; 2.7μ | precipitate | | |
| 40 | 473-G51 | (0.2% Byk 348 + 7.6% Byk 190 + 0.5% PVP | 24 nm (86%); 230 nm (13%) | Liquid with a | | |
| | | K-30) in [1% AMP in H₂O (pH = 11.5) + 30% NMP] | | small amount | | |
| | | | | of precipitate | | |
| 41 | 473-G51 | (0.2% Byk 348 + 7.6% Byk 190 + 0.5% PVP | 20 nm (70%); 230 nm (29%) | Liquid with a | 8.2 cp | 6.5 cp |
| | | K-15) in [0.5% AMP in H₂O (pH = 10.9) + 20% | | small amount | | |
| | | NMP] | | of precipitate | | |
| 42 | 473-G51 | (0.2% Byk 348 + 7.6% Byk 190 + 1.0% PVP | 25 nm (82%); 230 nm (17%) | Liquid with a a | 7.2 cp | 5.0 cp |
| | | K-15) in [0.5% AMP in H₂O (pH = 10.9) + 20% | | small amount | | |
| | | NMP] | | of precipitate | | |
| 43 | 473-G51 | (0.1% Byk 333 + 7.6% Byk 163) in (Dowanol DB + | There are big peaks | Liquid with | | |
| | | 30% PMA) | at 1μ and 2.7μ | precipitate | | |

The results shown in Table 2 demonstrate that useful water-based ink formulations could be prepared using silver nano powder 473-G51. This powder was obtained in the presence of Span in hexadecanol followed by washing by ethanol up to practically exhaustive elimination of organic substances. BYK 190 (in combination with wetting agent BYK 348) was found to be a useful dispersing agent for this nano powder in combination with PVP K-15 and K-30. In addition, NMP, PMA, Dowanol DB and n-propanol, were used as co-solvents and humectants.

The pH of the compositions was adjusted by AMP (2-amino-2-methyl-propanol). Several experiments were carried out with 1% AMP in water (pH 11.5). Dispersions were characterized by size distribution containing usually 4 peaks (about 20 nm, 230 nm, and 2 weak peaks at 1 μm and 2.7 μm). A decrease in AMP concentration to 0.5% resulted in a decrease in pH value to 10.9. Such a correction of pH resulted in an improvement of the dispersion characteristics.

As seen from Table 2, Examples 41 and 42 are characterized by only two peaks in the size distribution graph: 20-25 nm (70-86%) and 230 nm (13-29%). These formulations exhibited particularly useful viscosities for ink jet printing.

### Examples 44-145

Examples 44-145 describe additional water-based compositions. The constituents and properties of the individual compositions are listed in Table 3. The compositions, each of which, except as noted, included 60% by weight of silver nano powder No. 471-W51 (prepared as described in Example 28), were prepared as follows: 6 g of liquid carrier having the composition set forth in Table 3 was homogenized using a Dispermat (VMA-GETZMANN GMBH) at 4000 rpm. 9 g of silver nano powder was added gradually and then homogenization was performed for 10 min at 6000 rpm. The particle size measurements were measured with the use of HPPS (Malvern Instruments) for dispersions diluted in a liquid similar to that of the dispersion. The measurements were carried out only for liquid-phase dispersions. Some of the dispersions formed pastes after homogenization; these pastes were not further studied.

TABLE 3
Water-based formulations with NanoPowder product 471-W51

| Example | Sample | Dispersants, wetting agents and solvents | Size by volume distribution | Rheological properties | Viscosity |
|---|---|---|---|---|---|
| 44 | 471-W51-Ag/Cu | 7.6% Byk 192 in (0.1% NH₄OH + 10% DPM) | Peaks until 1μ | Liquid with precipitate | |
| | alloy stabilized by | | | | |
| | Tamol 1124 | | | | |
| 45 | 471-W51-Ag/Cu | 7.0% T-1124 in (H₂O + 10% DPM) | Peaks until 2.6μ | Liquid with | |
| | alloy stabilized by | | | precipitate | |
| | Tamol 1124 | | | | |
| 46 | 471-W51-Ag/Cu | 7.0% T 1124 in 1M NaOH | Peaks until 2.6μ | Liquid with | |
| | alloy stabilized by | | | precipitate | |
| | Tamol 1124 | | | | |
| 47 | 471-W51-Ag/Cu | 7.6% Byk 192 in (0.1% NH₄OH + 10% | Peaks until 1μ | Liquid with | |
| | alloy stabilized by | PMA) | | precipitate | |
| | Tamol 1124 | | | | |
| 48 | 471-W51-Ag/Cu | 10.5% Byk 192 in (0.1% NH₄OH + 10% | Peaks until 2.7μ | Liquid with | |
| | alloy stabilized by | PMA) | | precipitate | |
| | Tamol 1124 | | | | |
| 49 | 471-W51-Ag/Cu | 4.5% Byk 192 in (0.1% NH₄OH + 10% | Peaks until 2.7μ | Liquid with | |
| | alloy stabilized by | PMA) | | precipitate | |
| | Tamol 1124 | | | | |
| 50 | 471-W51-Ag/Cu | 7.6% Byk 190 in (0.1% NH₄OH + 10% | Peaks until 2.7μ | Liquid with | |
| | alloy stabilized by | PMA) | | precipitate | |
| | Tamol 1124 | | | | |
| 51 | 471-W51-Ag/Cu | 7.6% Betaine in (0.1% NH₄OH + 10% | Peaks until 1μ | Liquid with | |
| | alloy stabilized by | PMA) | | precipitate | |
| | Tamol 1124 | | | | |
| 52 | 471-W51-Ag/Cu | 1.5% Betaine in (0.1% NH₄OH + 10% | 2.5μ | Liquid with | |
| | alloy stabilized by | PMA) | | precipitate | |
| | Tamol 1124 | | | | |
| 53 | 471-W51-Ag/Cu | 1.5% Sodium Laureth Sulfosuccinate in | 1.6μ; 2.5μ | Liquid with | |
| | alloy stabilized by | (H₂O + 10% PMA) | | precipitate | |
| | Tamol 1124 | | | | |
| 54 | 471-W51-Ag/Cu | 1.5% Sodium Laureth Sulfate in | 1μ; 1.5μ | Liquid with | |
| | alloy stabilized by | (H₂O + 10% PMA) | | precipitate | |
| | Tamol 1124 | | | | |
| 55 | 471-W51-Ag/Cu | 7.6% Tego 740w in (H₂O + 10% PMA) | Peaks until 1μ | Liquid with | 99.6 cp |
| | alloy stabilized by | | | precipitate | (25° C.) |
| | Tamol 1124 | | | | |
| 56 | 471-W51-Ag/Cu | 4.5% Tego 740w in (H₂O + 10% PMA) | Peaks until 1μ; small peak | Liquid with | |
| | alloy stabilized by | | at 2.7μ | precipitate | |
| | Tamol 1124 | | | | |
| 57 | 471-W51-Ag/Cu | 12% Tego 740w in (H₂O + 10% PMA) | Peaks at 940 nm; 2.7μ | Liquid with | |
| | alloy stabilized by | | | precipitate | |
| | Tamol 1124 | | | | |
| 58 | 471-W51-Ag/Cu | 7.6% Tego 740w in (H₂O + 10% DPM) | Peaks at 940 nm; 2.7μ | Liquid with | |
| | alloy stabilized by | | | precipitate | |
| | Tamol 1124 | | | | |
| 59 | 471-W51-Ag/Cu | 3% AOT in (H₂O + 10% PMA) | 2.4μ | Liquid with | |
| | alloy stabilized by | | | precipitate | |
| | Tamol 1124 | | | | |
| 60 | 471-W51-Ag/Cu | 7.6% Tego 740w in (0.1% | Peaks at 940 nm; 2.7μ | Liquid with | |
| | alloy stabilized by | NH₄OH + 10% PMA) | | precipitate | |
| | Tamol 1124 | | | | |
| 61 | 471-W51-Ag/Cu | 7.6% Tego 735w in (H₂O + 10% PMA) | 2.4μ | Liquid with | |
| | alloy stabilized by | | | precipitate | |
| | Tamol 1124 | | | | |
| 62 | 471-W51-Ag/Cu | 45% Byk 190 in (H₂O + 10% PMA) | Peaks until 600 nm; small | Liquid with | |
| | alloy stabilized by | | peak at 2μ | precipitate | |
| | Tamol 1124 | | | | |
| 63 | 471-W51-Ag/Cu | 15% (active) Tego 750w in (H₂O + 10% | Peaks at 940 nm and 2.7μ | Liquid with | |
| | alloy stabilized by | PMA) | | precipitate | |
| | Tamol 1124 | | | | |
| 64 | 471-W51-Ag/Cu | 7.6% Disperbyk in (H₂O + 10% PMA) | | Paste | |
| | alloy stabilized by | | | | |
| | Tamol 1124 | | | | |
| 65 | 471-W51-Ag/Cu | 0.5% PDAC (Med. M.W.) in (H₂O + 5% | | Paste | |
| | alloy stabilized by | Glycerol) | | | |
| | Tamol 1124 | | | | |
| 66 | 471-W51-Ag/Cu | 7.6% Tego 740w in (H₂O + 20% PMA) | | Liquid with | 185 cp |
| | alloy stabilized by | | | precipitate | (25° C.) |
| | Tamol 1124 | | | | |
| 67 | 471-W51-Ag/Cu | (4.5% Tego 740w + 5% Na-citrate) in | 616 nm (26%); 933 nm | Liquid | |
| | alloy stabilized by | (H₂O + 10% PMA) | (73%); 2.7μ (2%) | with | |
| | Tamol 1124 | | | precipitate | |
| 68 | 471-W51-Ag/Cu | 7.6% Dispex A-40 in H₂O | | Paste | |
| | alloy stabilized by | | | | |
| | Tamol 1124 | | | | |
| 69 | 471-W51-Ag/Cu | (1% Byk 333 + 7.6% Byk 190) in | Peak at 2.7μ | Liquid with | |
| | alloy stabilized by | (H₂O + 10% PMA) | | precipitate | |
| | Tamol 1124 | | | | |
| 70 | 471-W51-Ag/Cu | (1% Tween 20 + 7.6% Byk 190) in | Peaks until 600 nm | Liquid with | |
| | alloy stabilized by | (H₂O + 10% PMA) | | precipitate | |
| | Tamol 1124 | | | | |
| 71 | 471-W51-Ag/Cu | (1% Tween 20 + 7.6% Byk 190) in | Peaks until 600 nm | Liquid with | |
| | alloy stabilized by | (H₂O + 15% IPA + 10% PMA) | | precipitate | |
| | Tamol 1124 | | | | |
| 72 | 471-W51-Ag/Cu | (1% Tween 20 + 7.6% Byk 190) in | Peaks until 600 nm | Liquid with | |
| | alloy stabilized by | (H₂O + 5% IPA + 10% PMA) | | precipitate | |
| | Tamol 1124 | | | | |
| 73 | 471-W51-Ag/Cu | 7.6% Tween 20 in (H₂O + 10% PMA) | Sometimes a peak at 2.7μ | Liquid with | |
| | alloy stabilized by | | appears | precipitate | |
| | Tamol 1124 | | | | |
| 74 | 471-W51-Ag/Cu | 7.6% Tween 20 in (H₂O + 10% | Peaks until 600 nm, small | Liquid with | |
| | alloy stabilized by | Sulfolan) | peak at 2.7μ | precipitate | |
| | Tamol 1124 | | | | |
| 75 | 471-W51-Ag/Cu | 7.6% Tween 20 in (H₂O + 10% | Peaks until 600 nm, small | Liquid with | |
| | alloy stabilized by | Diethyleneglycol) | peak at 2.7μ | precipitate | |
| | Tamol 1124 | | | | |
| 76 | 471-W51-Ag/Cu | (7.6% Tween 20 + 0.5% NMP) in | Peaks until 600 nm, small | Liquid with | |
| | alloy stabilized by | (H₂O + 10% PMA) | peak at 2.7μ | precipitate | |
| | Tamol 1124 | | | | |
| 77 | 471-W51-Ag/Cu | (7.6% Tween 20 + 1% PVP K-40) in | Peaks until 600 nm, small | Liquid with | |
| | alloy stabilized by | (H₂O + 10% PMA) | peak at 2.7μ | precipitate | |
| | Tamol 1124 | | | | |
| 78 | 471-W51-Ag/Cu | (7.6% Tween 20 + 1% Joncryl 537) in | Sometimes a small peak at | Liquid with | |
| | alloy stabilized by | (H₂O + 10% PMA) | 2.7μ appears | precipitate | |
| | Tamol 1124 | | | | |
| 79 | 471-W51-Ag/Cu | (7.6% Tween 20 + 1% Joncryl 8003) in | Sometimes there is a small | Liquid with | |
| | alloy stabilized by | (H₂O + 10% PMA) | peak at 2.7μ | precipitate | |
| | Tamol 1124 | | | | |
| 80 | 471-W51-Ag/Cu | (7.5% Nonidet in | There are peaks at 940 nm; | Paste | |
| | alloy stabilized by | (Triethanolamine/H₂O = 1:3) | 2.7μ | | |
| | Tamol 1124 | | | | |
| 81 | 471-W51-Ag/Cu | 3% Nonidet in 10% Triethanolamine | There are peaks at 940 nm; | Paste | |
| | alloy stabilized by | | 2.7μ | | |
| | Tamol 1124 | | | | |
| 82 | 471-W51-Ag/Cu | (1% Tween 20 + 7.6% Byk 190) in H₂O | 20 nm (37%) 236.2 (2%) | Liquid with | 33.2 cp |
| | alloy stabilized by | | | precipitate | (25° C.) |
| | Tamol 1124 | | | | |
| 83 | 471-W51-Ag/Cu | (1% Tween 20 + 7.6% Byk 190) in H₂O | 20 nm (37%) 236.2 (2%) | Liquid with | 33.2 cp |
| | alloy stabilized by | | | precipitate | (25° C.) |
| | Tamol 1124 | | | | |
| 84 | 471-W51-Ag/Cu | (1% Tween 20 + 7.6% Byk 190 + 0.5% | There is a peak at 2.7μ | Liquid with | |
| | alloy stabilized by | Byk 348) in (H₂O + 10% PMA) | | precipitate | |
| | Tamol 1124 | | | | |
| 85 | 471-W51-Ag/Cu | (0.2% Tween 20 + 7.6% Byk 190) in | There is a peak at 2.7μ | Liquid with | |
| | alloy stabilized by | (H₂O + 10% PMA) | | precipitate | |
| | Tamol 1124 | | | | |
| 86 | 471-W51-Ag/Cu | 7.6% Byk 190 in (H₂O + 10% PMA) | There are peaks at 940 nm | Liquid with | |
| | alloy stabilized by | | and 2.7μ | precipitate | |
| | Tamol 1124 | | | | |
| 87 | 471-W51-Ag/Cu | 15% Byk 190 in (H₂O + 10% PMA) | Sometimes a peak at 2.7μ | Liquid with | |
| | alloy stabilized by | | appears | precipitate | |
| | Tamol 1124 | | | | |
| 88 | 471-W51-Ag/Cu | (0.5% Tween 20 + 7.6% Byk 190) in | Sometimes peaks at 940 nm | Liquid with | |
| | alloy stabilized by | (H₂O + 10% PMA) | and 2.7μ appear | precipitate | |
| | Tamol 1124 | | | | |
| 89 | 471-W51-Ag/Cu | (1% Tween 20 + 7.6% Byk 190) in | Sometimes peaks at 940 nm | Liquid with | |
| | alloy stabilized by | (H₂O + 10% Dowanol DB) | and 2.7μ appear | precipitate | |
| | Tamol 1124 | | | | |
| 90 | 471-W51-Ag/Cu | (2.0% Byk 154 + 7.6% Byk 181) in | 940 nm; 2.7μ | Almost | |
| | alloy stabilized by | (H₂O + 10% Ethanol) | | paste | |
| | Tamol 1124 | | | | |
| 91 | 471-W51-Ag/Cu | (1.0% Byk 181 + 7.6% Byk 190) in | 18 nm; 220 nm | Liquid with | |
| | alloy stabilized by | (H₂O + 10% Ethanol) | | precipitate | |
| | Tamol 1124 | | | | |
| 92 | 471-W51-Ag/Cu | (1% Urea + 1% Byk 181 + 7.6% Byk | 18 nm; 220 nm | Liquid with | |
| | alloy stabilized by | 190) in (H₂O + 10% Ethanol) | | precipitate | |
| | Tamol 1124 | | | | |
| 93 | 471-W51-Ag/Cu | (1% Byk 181 + 7.6% Byk 190) in | Peaks until 230 nm | Liquid with | |
| | alloy stabilized by | (H₂O + 10% PM) | | precipitate | |
| | Tamol 1124 | | | | |
| 94 | 471-W51-Ag/Cu | (1% Byk 181 + 7.6% Byk 154) in | Peaks at 385, 583.1 nm | Almost | |
| | alloy stabilized by | (H₂O + 10% Ethanol) | | paste | |
| | Tamol 1124 | | | | |
| 95 | 471-W51-Ag/Cu | 7.6% Tween 20 in (H₂O + 10% DMF) | 10-18 nm; 240 nm; 400 nm; | Liquid with | |
| | alloy stabilized by | | small peak 2.7μ | precipitate | |
| | Tamol 1124 | | | | |
| 96 | 471-W51-Ag/Cu | (1% Byk 181 + 10% Byk 154) in | 500-600 nm | Almost | |
| | alloy stabilized by | (H₂O + 10% Ethanol) | | paste | |
| | Tamol 1124 | | | | |
| 97 | 471-W51-Ag/Cu | (1% Byk 181 + 7.6% Byk 190) in | 24 nm; 230 nm; sometimes | Liquid with | |
| | alloy stabilized by | (H₂O + 20% Ethanol) | small peak at 2.7μ appears | precipitate | |
| | Tamol 1124 | | | | |
| 98 | 471-W51-Ag/Cu | (1% Byk 181 + 7.6% Byk 190) in (H₂O + 20% DMF) | 20 nm; 230 nm; small peak | Liquid with | |
| | alloy stabilized by | | at 2.7μ | precipitate | |
| | Tamol 1124 | | | | |
| 99 | 471-W51-Ag/Cu | (1% Urea + 1% Tween 20 + 7.6% Byk | 20-30 nm; 230 nm | Liquid with | |
| | alloy stabilized by | 190) in (H₂O + 10% DMF + 10% | | precipitate | |
| | Tamol 1124 | Ethanol) | | | |
| 100 | 471-W51-Ag/Cu | (1% Urea + 7.6% Tween 20) in | 17-18 nm; 200 nm; small | Liquid with | |
| | alloy stabilized by | (H₂O + 10% DMF) | peak at 2.7μ | precipitate | |
| | Tamol 1124 | | | | |
| 101 | 471-W51-Ag/Cu | (1% Urea + 7.6% Tween 20) in | 25 nm; 230 nm; sometimes | Liquid with | 36.2 cp |
| | alloy stabilized by | (H₂O + 10% DMF + 10% PMA) | a small peak at 2.7μ | precipitate | (25° C.) |
| | Tamol 1124 | | appears | | 21. cp |
| | | | | | (45° C.) |
| 102 | 471-W51-Ag/Cu | (1% Urea + 7.6% Tween 20) in | 20 nm; 230 nm; sometimes | Liquid with | 56.4 cp |
| | alloy stabilized by | (H₂O + 10% DMF + 10% Dow.DB) | a small peak at 2.7μ | precipitate | (25° C.) |
| | Tamol 1124 | | appears | | 50. cp |
| | | | | | (45° C.) |
| 103 | 471-W51-Ag/Cu | (1% Urea + 1% Byk 181 + 7.6% Byk | 20 nm; 230 nm; sometimes | Liquid with | 34.7 cp |
| | alloy stabilized by | 190) in (H₂O + 10% | a small peak at 2.7μ | precipitate | (25° C.) |
| | Tamol 1124 | DMF + 10% Dowanol DB) | appears | | 19.1 cp |
| | | | | | (45° C.) |
| 104 | 471-W51-Ag/Cu | (1% Urea + 1% Byk 181 + 7.6% Byk | 20 nm; 230 nm; sometimes | Liquid with | 56.4 cp |
| | alloy stabilized by | 190) in (H₂O + 10% DMF + 10% PMA) | a small peak at 2.7μ | precipitate | (25° C.) |
| | Tamol 1124 | | appears | | 25.0 cp |
| | | | | | (45° C.) |
| 105 | 471-W51-Ag/Cu | 7.6% Tween 20 in (H₂O + 20% Ethanol + | 20 nm; 230 nm; sometimes | Liquid with | |
| | alloy stabilized by | 10% PMA) | a small peak at 2.7μ | precipitate | |
| | Tamol 1124 | | appears | | |
| 106 | 471-W51-Ag/Cu | 7.6% Tween 20 in (H₂O + 20% | 20 nm; 230 nm; sometimes | Liquid with | |
| | alloy stabilized by | Ethanol + 10% Dowanol DB) | a small peak at 2.7μ | precipitate | |
| | Tamol 1124 | | appears | | |
| 107 | 471-W51-Ag/Cu | (1% Byk 181 + 7.6% Byk 180) in | 500 nm | Almost | |
| | alloy stabilized by | (H₂O + 10% IPA + 10% Dowanol DB) | | paste | |
| | Tamol 1124 | | | | |
| 108 | 471-W51-Ag/Cu | 7.6% Tween 20 in H₂O + (1% Span 20 | 20-30 nm; 230 nm; small | Liquid with | |
| | alloy stabilized by | in 10% IPA + 10% Dowanol DB) | peak at 2.7μ appears | precipitate | |
| | Tamol 1124 | | | | |
| 109 | 471-W51-Ag/Cu | 7.6% Tween 20 in (H₂O + 20% | 230 nm and sometimes a | Liquid with | |
| | alloy stabilized by | IPA + 10% Dowanol DB) | small peak at 2.7μ appears | precipitate | |
| | Tamol 1124 | | | | |
| 110 | 471-W51-Ag/Cu | 7.6% Tween 20 in (H₂O + 20% IPA) | 20 nm; 230 nm | Liquid with | |
| | alloy stabilized by | | | precipitate | |
| | Tamol 1124 | | | | |
| 111 | 471-W51-Ag/Cu | 7.6% Tween 80 in (H₂O + 20% IPA) | 20 nm; 230 nm | Liquid with | |
| | alloy stabilized by | | | precipitate | |
| | Tamol 1124 | | | | |
| 112 | 471-W51-Ag/Cu | 5% CTAC in (H₂O + 20% IPA) | 20 nm; 230 nm | Paste | |
| | alloy stabilized by | | | | |
| | Tamol 1124 | | | | |
| 113 | 471-W51-Ag/Cu | 10% CTAC in (H₂O + 20% IPA) | 1μ; 2μ | Paste | |
| | alloy stabilized by | | | | |
| | Tamol 1124 | | | | |
| 114 | 471-W51-Ag/Cu | (2% Daxad 19 + 7.6% Byk 190) in | 600 nm; 700 nm | Liquid with | |
| | alloy stabilized by | (H₂O + 20% IPA) | | precipitate | |
| | Tamol 1124 | | | | |
| 115 | 471-W51-Ag/Cu alloy | (7.6% BasF 104 + 0.025% NH₄OH) in (H₂O + 20% IPA) | 20 nm (80%); 230 nm (14%); sometimes a | Liquid with | |
| | stabilized by Tamol 1124 | | small peak at 2.7μ appears | precipitate | |
| 116 | 471-W51-Ag/Cu alloy | (5% BasF 104 + 0.025% NH₄OH) in (H₂O + 20% | 10-12 nm (50%); 230 nm (7%); sometimes | Liquid with | |
| | stabilized by Tamol 1124 | IPA) | a small peak at 2.7μ appears | precipitate | |
| 117 | 471-W51-Ag/Cu alloy | (7.6% Tween 20 + 0.025% NH₄OH) in (H₂O + 20% | 10-12 nm (50%); 230 nm (7%); sometimes | Liquid with | |
| | stabilized by Tamol 1124 | IPA) | a small peak at 2.7μ appears | precipitate | |
| 118 | 471-W51-Ag/Cu alloy | (1% Tween 20 + 7.6% Bk 190 + 0.1% NH₄OH) in | 10-12 nm (50%); 230 nm (7%); sometimes | Liquid with | |
| | stabilized by Tamol 1124 | (H₂O + 20% IPA) | a small peak at 2.7μ appears | precipitate | |
| 119 | 471-W51-Ag/Cu alloy | (1% Tween 20 + 7.6% Bk 190 + 0.1% NH₄OH) in | 10-12 nm (50%); 230 nm (7%); sometimes | Liquid with | |
| | stabilized by Tamol 1124 | (H₂O + 20% Diglyme) | a small peak at 2.7μ appears | precipitate | |
| 120 | 471-W51-Ag/Cu alloy | (45% Byk 190 + 1% Tween 20 + 0.1% NH₄OH) in | 420 nm; 600 nm; 1μ; 2μ | Liquid with | |
| | stabilized by Tamol 1124 | (H₂O + 20% Diglyme) | | precipitate | |
| 121 | 471-W51-Ag/Cu alloy | (2% L-77 + 7.6% Byk 190 + 0.1% NH₄OH) in | 49 nm (26%); 230 nm (25%); sometimes | Liquid with | |
| | stabilized by Tamol 1124 | (H₂O + 20% IPA + 10% Dowanol DB) | small peaks at 1μ and 2.7μ appear | precipitate | |
| 122 | 471-W51-Ag/Cu alloy | (1% Byk 181 + 7.6% Byk 180) in (H₂O + 10% | 450 nm; 600 nm | Liquid with | |
| | stabilized by Tamol 1124 | Diglyme + 10% Dowanol DB) | | precipitate | |
| 123 | 471-W51-Ag/Cu alloy | (1% L-77 + 7.6% Byk 180) in (H₂O + 20% | Peaks until 1μ | Paste | |
| | stabilized by Tamol 1124 | Dowanol DB) | | | |
| 124 | 471-W51-Ag/Cu alloy | (2% Tween 20 + 7.6% Byk 180 in (H₂O + 20% | 8 nm (90%); 200 nm; 400 nm; 600 nm (2-3%) | Liquid with | |
| | stabilized by Tamol 1124 | Diglyme) | | precipitate | |
| 125 | 471-W51-Ag/Cu alloy | (0.5% Tween 20 + 7.6% Byk 180) in (H₂O + 20% | 15 nm (60%); 1μ (33%); 2.7μ | Liquid with | |
| | stabilized by Tamol 1124 | Diglyme) | | precipitate | |
| 126 | 471-W51-Ag/Cu alloy | (1% Byk 348 + 7.6% Byk 180) in (H₂O + 20% | 20 nm (24%); 240 nm (4%); 400 nm (9%); | Liquid with | |
| | stabilized by Tamol 1124 | Diglyme) | 1μ (30%) | precipitate | |
| 127 | 471-W51-Ag/Cu alloy | (0.91% Byk 181 + 13.6% Byk 180) in (H₂O + 9.1% | 400 nm | Liquid with | |
| | stabilized by Tamol 1124 | Diglyme + 9.1% Dowanol DB) | | precipitate | |
| 128 | 471-W51-Ag/Cu alloy | (1% Byk 181 + 5% Byk 180) in (H₂O + 10% | Big peaks at 1μ and 2.7μ | Liquid with | |
| | stabilized by Tamol 1124 | Diglyme + 10% Dowanol DB) | | precipitate | |
| 129 | 471-W51-Ag/Cu alloy | (4% Urea + 1% Byk 181 + 7.6% Byk 180) in | Big peaks at 1μ and 2.7μ | Liquid with | |
| | stabilized by Tamol 1124 | (H₂O + 10% Diglyme + 10% Dowanol DB) | | precipitate | |
| 130 | 471-W51-Ag/Cu alloy | (0.2% SDS + 1% Byk 181 + 7.6% Byk 180) in | Big peaks at 1μ | Liquid with | |
| | stabilized by Tamol 1124 | (H₂O + 10% Diglyme + 10% Dowanol DB) | | precipitate | |
| 131 | 471-W51-Ag/Cu alloy | (1% Byk 181 + 10% Byk 180) in (H₂O + 10% | Peaks at 1μ and 2.7μ | Liquid with | |
| | stabilized by Tamol 1124 | Diglyme + 10% Dowanol DB) | | precipitate | |
| 132 | 471-W51-Ag/Cu alloy | (0.8% PVP K-30 + 0.5% Byk 348 + 7.6% Byk | 20 nm; 230 nm; sometimes a peak at 2.7μ | Liquid with | |
| | stabilized by Tamol 1124 | 190 in [0.04% AMP in H₂O(pH = 10) + 40% | appears | precipitate | |
| | | IPA + 5% DPM) | | | |
| 133 | 471-W51-Ag/Cu alloy | (0.8% PVP K-30 + 0.5% Tween 20 + 0.5% | | Paste | |
| | stabilized by Tamol 1124 | Byk 348 + 15.2% Solsperse 44000) in (0.04% | | | |
| | | AMP in H₂O(pH = 10) + 40% IPA + 5% DPM) | | | |
| 134 | 471-W51-Ag/Cu alloy | (0.5% Tween 20 + 0.5% Byk 348 + 7.6% | | Paste | |
| | stabilized by Tamol 1124 | Solsperse 43.000 + 0.8% PVP (K-30) in (40% | | | |
| | | IPA + 5% DPM + 0.04% AMP in H₂O | | | |
| | | (pH = 10)] | | | |
| 135 | 471-W51-Ag/Cu alloy | (0.5% Tween 20 + 0.5% Byk 348 + 7.6% Byk | 20 nm; 230 nm; sometimes a small peak at | Liquid with precipitate | |
| | stabilized by Tamol 1124 | 190 + 0.5% PVP K-30) in [0.04% AMP in | 2.7μ appears | | |
| | | H₂O (pH = 10) + 20% NMP]] | | | |
| 136 | 40% 471-W51-Ag/Cu alloy | (0.5% Tween 20 + 0.5% Byk 348 + 7.6% Byk | 20 nm; 230 nm; sometimes a small peak at | Liquid with small and soft precipitate | |
| | stabilized by Tamol 1124 | 190 + 0.5% PVP K-30) in [0.04% AMP in | 2.7μ appears | | |
| | | H₂O (pH = 10) + 20% NMP]] | | | |
| 137 | 40% 471-W51-Ag/Cu alloy | (0.2 Byk 348 + 7.6% Byk 190 + 0.5% PVP K- | 20 nm; 230 nm; sometimes a small peak at | Liquid with small and soft precipitate | 10.9 cp |
| | stabilized by Tamol 1124 | 30) in [1% AMP in H₂O (pH = 11.5) + 20% | 2.7μ appears | | (25° C.) |
| | | NMP] | | | 6.54 |
| 138 | 40% 471-W51-Ag/Cu alloy | (0.2 Byk 348 + 7.6% Byk 190 + 0.5% PVP K- | 20 nm; 230 nm; sometimes a small peak at | Liquid with small and soft precipitate | |
| | stabilized by Tamol 1124 | 30) in [1% AMP in H₂O (pH = 11.5) + 20% | 2.7μ appears | | |
| | | NMP] | | | |
| 139 | 60% 471-W51-Ag/Cu alloy | 0.2% Byk 348 + 7.6% Atlox 4913) in [1% | 20 nm; 230 nm | Liquid with | |
| | stabilized by Tamol 1124 | AMP in H₂O (pH = 11.5) + 20% NMP] | | precipitate | |
| 140 | 471-W51-Ag/Cu alloy | (0.2 Byk 348 + 7.6% Daxad 19) in [1% AMP | | Paste | |
| | stabilized by Tamol 1124 | in H₂O (pH = 11.5) + 20% NMP] | | | |
| 141 | 471-W51-Ag/Cu alloy | (0.2 Byk 348 + 5% Solsperse 44000) in [1% | 20 nm; 230 nm; sometimes a small peat at | Liquid with | |
| | stabilized by Tamol 1124 | AMP in H₂O (pH = 11.5) + 20% NMP] | 2.7μ appears | precipitate | |
| 142 | 471-W51-Ag/Cu alloy | (0.2 Byk 348 + 7.6% Solsperse 44000) in [1% | 20 nm; 230 nm; sometimes a small peat at | Liquid with | |
| | stabilized by Tamol 1124 | AMP in H₂O (pH = 11.5) + 20% NMP] | 2.7μ appears | precipitate | |
| 143 | 471-W51-Ag/Cu alloy | (0.2 Byk 348 + 7.6% Byk 190 + 0.5% PVP K- | 20 nm; 230 nm (15%); 1μ; 2.7μ | Liquid with | |
| | stabilized by Tamol 1124 | 30) in [1% AMP in H₂O (pH = 11.5) + 20% n- | | precipitate | |
| | | propanol] | | | |
| 144 | 471-W51-Ag/Cu alloy | (0.2 Byk 348 + 7.6% Byk 190 + 0.5% PVP K- | 20 nm (70%); 230 nm (14%); sometimes a | Liquid with | |
| | stabilized by Tamol 1124 | 30) in [1% AMP in H₂O (pH = 11.5) + 30% | small peat at 2.7μ appears | precipitate | |
| | | NMP] | | | |
| 145 | 471-W51-Ag/Cu alloy | (0.2 Byk 348 + 7.6% Byk 190 + 0.5% PVP K- | 20 nm (70%); 230 nm (14%); sometimes a | Liquid with | |
| | stabilized by Tamol 1124 | 30) in [1% AMP in H₂O (pH = 11.5) + 20% n-propanol + 10% | small peat at 2.7μ appears | precipitate | |
| | | NMP] | | | |

The results shown in Table 3 demonstrate that the best dispersions could be obtained at high pH values, e.g., about 10. Therefore, experiments were carried out with the addition of ammonia solution, and then with an organic amine (AMP) to avoid NH₃ evaporation. Low concentrations of AMP were used (e.g., 0.04% AMP in water gives pH=10). Because the preparation of silver nano powder dispersions results in a decrease in pH to 9, the AMP concentration in all experiments was 1%. The best dispersions (very diluted, without a dispersant or wetting agent) were obtained with the use of isopropanol and ethanol as humectants; the optimal concentrations were found to be 40% for both additives. Several formulations also contained DPM as an additive in order to suppress evaporation.

As seen in Table 3, most of the formulations contained compact precipitates and had relatively high viscosities. A decrease in silver nano powder concentration from 60% to 40% resulted in a decrease in the amount of precipitate, which also became less compact. Viscosities of formulations containing 40% of silver nano powder (e.g., Examples 137 and 138) were 10.9 cP at 25° C. and 6.9 cP at 45° C.

### Examples 146-167

Examples 146-167 describe additional water-based compositions. The constituents and properties of the individual compositions are listed in Table 4. The compositions, each of which included 60% by weight of silver nano powder No. 1440 (prepared in the presence of Daxad 19 stabilizer following the procedures generally described in U.S. Pat. No. 5,476,535 and PCT application WO 2004/000491 A2), were prepared as follows: 6 g of liquid carrier having the composition set forth in Table 4 was homogenized using a Dispermat (VMA-GETZMANN GMBH) at 4000 rpm. 9 g of silver nano powder was added gradually and then homogenization was performed for 10 min at 6000 rpm. The particle size measurements were measured with the use of HPPS (Malvern Instruments) for dispersions diluted in a liquid similar to that of the dispersion. The measurements were carried out only for liquid-phase dispersions. Some of the dispersions formed pastes after homogenization; these pastes were not further studied.

TABLE 4
Water-based formulations with NanoPowder product 1440 stabilized by Daxad 19

| | | Dispersants, wetting agents and | | | |
|---|---|---|---|---|---|
| Example | Sample | solvents | Size by volume distributions | Rheological properties | Viscosity |
| 146 | 1440 (Lot AS 1015) | 2% SDS in (H₂O + 10% PMA) | 2.7μ | Paste | |
| | Stabilized by Daxad 19 | | | | |
| 147 | 1440 (Lot AS 1015) | 15% Byk 190 in (0.1% NH₄OH + 10% | 935 nm; 2μ | Liquid with precipitate | |
| | Stabilized by Daxad 19 | PMA) | | | |
| 148 | 1440 (Lot AS 1015) | 7.6% Tego 740 W in H₂O | 2.7μ | Pastse | |
| | Stabilized by Daxad 19 | | | | |
| 149 | 1440 (Lot AS 1015) | 7.6% Byk 190 in (H₂O + 10% PMA) | 248.7 nm (18%); 425.5 nm | Liquid with precipitate | 11.3 cp |
| | Stabilized by Daxad 19 | | (56%); 595.1 nm (15%); and | | (25° C.) |
| | | | small peaks at 940 nm and 2.7μ | | 10.6 cp |
| | | | | | (45° C.) |
| 150 | 1440 (Lot AS 1015) | 15% Byk 190 in H₂O | Peaks until 600μ and a small | Liquid with precipitate | |
| | Stabilized by Daxad 19 | | peak at 2.7μ | | |
| 151 | 1440 (Lot AS 1015) | 7.5% Byk 190 in H₂O | There are peaks at 940 nm and | Liquid with precipitate | |
| | Stabilized by Daxad 19 | | 2.7μ | | |
| 152 | 1440 (Lot AS 1015) | 15% Byk 190 in (H₂O + 10% DPM) | There are peaks at 940 nm and | Liquid with precipitate | |
| | Stabilized by Daxad 19 | | 2.7μ | | |
| 153 | 1440 (Lot AS 1015) | 7.5% Byk 190 in (H₂O + 10% DPM) | There are peaks at 940 nm and | Liquid with precipitate | |
| | Stabilized by Daxad 19 | | 2.7μ | | |
| 154 | 1440 (Lot AS 1015) | 15% Byk 190 in (H₂O + 10% PMA) | There are peaks at 940 nm and | Liquid with precipitate | |
| | Stabilized by Daxad 19 | | 2.7μ | | |
| 155 | 1440 (Lot AS 1015) | 7.6% Dispex A40 in H₂O | There are peaks at 940 nm and | Liquid with precipitate | |
| | Stabilized by Daxad 19 | | 2.7μ | | |
| 156 | 1440 (Lot AS 1015) | 7.6% Na-polyacrylic acid 2100 in H₂O | There are peaks at 940 nm and | Liquid with precipitate | |
| | Stabilized by Daxad 19 | | 2.7μ | | |
| 157 | 1440 (Lot AS 1015) | (1% Tween 20 + 7.6% Byk 190) in | There are peaks at 940 nm and | Liquid with precipitate | |
| | Stabilized by Daxad 19 | (H₂O + 10% PMA) | 2.7μ | | |
| 158 | 1440 (Lot AS 1015) | 7.6% Tween 20 in (H₂O + 10% Sultolan) | | Paste | |
| | Stabilized by Daxad 19 | | | | |
| 159 | 1440 (Lot AS 1015) | 7.6% Tween 20 in (H₂O + 10% PMA) | | Paste | |
| | Stabilized by Daxad 19 | | | | |
| 160 | 1440 (Lot AS 1015) | (1% Byk 333 + 7.6% Byk 190) in | 940 nm; 2.7μ | Liquid with precipitate | |
| | Stabilized by Daxad 19 | (H₂O + 10% PMA) | | | |
| 161 | 1440 (Lot AS 1015) | (7.6% Byk 190 + 1% PVP K-30) in | 940 nm; 2.7μ | Liquid with precipitate | |
| | Stabilized by Daxad 19 | (H₂O + 10% PMA) | | | |
| 162 | 1440 (Lot AS 1015) | 3% Nonidet in 10% Triethanolamine | 940 nm; 2.7μ | Liquid with precipitate | |
| | Stabilized by Daxad 19 | | | | |
| 163 | 1440 (Lot AS 1037) | 7.6% Byk 9077 in PMA | Peaks until 1μ | Liquid with precipitate | |
| | Stabilized by Daxad 19 | | | | |
| 164 | 1440 (Lot AS 1037) | 7.6% Byk 9076 in PMA | Peaks until 1μ | Liquid with precipitate | |
| | Stabilized by Daxad 19 | | | | |
| 165 | 1440 (Lot AS 1037) | (1% Byk 181 + 7.6% Byk 154) in | | Paste | |
| | Stabilized by Daxad 19 | (H₂O + 10% Ethanol) | | | |
| 166 | 1440 (Lot AS 1037) | 7.6% Tween 20 in (H₂O + 20% DPA) | 200 nm; 400 nm; 2.7μ | Liquid with precipitate | |
| | Stabilized by Daxad 19 | | | | |
| 167 | 1440 (Lot AS 1037) | (7.6% Dasad 19 + 0.2% Byk 348) in (1% | | Paste | |
| | Stabilized by Daxad 19 | AMP in H₂O (pH = 11.5) + 20% NMP) | | | |

As shown in Table 4, most of the formulations contained particles with a size of about 1 and 2.7 μm. In addition, each formulation resulted in the formation of a paste or bulky precipitate.

### Examples 168-172

Examples 168-172 describe additional water and solvent-based compositions. The constituents and properties of the individual compositions are listed in Table 5. The compositions, each of which included 60% by weight of silver nano powder No. 473-SH or 44-052 (prepared following the procedures generally described in U.S. Pat. No. 5,476,535 and PCT application WO 2004/000491 A2), were prepared as follows: 6 g of liquid carrier having the composition set forth in Table 5 was homogenized using a Dispermat (VMA-GETZMANN GMBH) at 4000 rpm. 9 g of silver nano powder was added gradually and then homogenization was performed for 10 min at 6000 rpm. As shown in Table 5, each formulation formed a paste.

TABLE 5
Solvent and water-based formulations with NanoPowder
products 473-SH and 440-052

| | | | Rheological |
|---|---|---|---|
| Exampl | Sample | Dispersants, wetting agents and solvents | properties |
| 168 | 473-SH | (0.1% Byk 333 + 7.6% Byk 163) in (Dowanol DB + | Paste |
| | (Lot AS 1060) | 30% PMA) | |
| 169 | 473-SH | (0.2% Byk 348 + 7.6% Byk 190 + 0.5% PVP | Paste |
| | (Lot AS 1060) | K-30) in [1% AMP in H₂O (pH = 11.5) + 20% | |
| | | n-propanol] | |
| 170 | 473-SH | (0.2% Byk 348 + 7.6% Byk 190 + 0.5% PVP | Paste |
| | (Lot AS 1060) | K-30) in (H₂O + 20% n-propanol) | |
| 171 | 440-052 | (0.1% Byk 333 + 7.6% Byk 163) in (Dowanol | Paste |
| | (Lot AS 1055) | DB + 30% PMA) | |
| 172 | 440-052 | (0.2% Byk 348 + 7.6% Byk 190 + 0.5% PVP | Paste |
| | (Lot AS 1055) | K-30) in (H₂O + 20% n-propanol) | |

### Examples 173-178

The formulations described in Examples 173-178 are listed in Table 6, and were prepared following the procedure generally described in Examples 168-172 using either silver nano powder 471-W51 (prepared as described in Example 28) or 473-G51 (prepared as described in Example 26).

TABLE 6
Formulations for printing with the use of HP Deskjet 690

| | Ag | Ag | Solution | | |
|---|---|---|---|---|---|
| Example | sample | Concentrate | Additives | Solvent | Comments |
| 173 | 471-W51 | 30% | 0.5% PVP K-30 | 40% IPA | Initial formulation contained |
| | | | 1% Byk-348 | 5% DPM | 60% of Ag and was diluted |
| | | | 7.6% Byk-190 | 55% water, | twice before printing |
| | | | | pH = 10 | |
| 174 | 471-W51 | 50% | 0.5% PVP K-30 | 20% NMP | Initial formulation contained |
| | | | 0.5% Byk-348 | 0.04% AMP-95 | 60% of Ag and was diluted 1.2 |
| | | | 0.5% Tween 20 | in water, | times before printing |
| | | | 7.6% Byk-190 | pH = 10 | |
| 175 | 471-W51 | 40% | 0.2% PVP K-30 | 20% NMP | Initial formulation contained |
| | | | 1% Byk-348 | 1% AMP-95 | 40% of Ag |
| | | | 7.6% byk-190 | in water, | |
| | | | | pH = 11.5 | |
| 176 | 473-G51 | 60% | 0.2% PVP K-30 | 20% NMP | |
| | | | 1% Byk-348 | 1% AMP-95 | |
| | | | 7.6% Byk-190 | in water, | |
| | | | | pH = 11.5 | |
| 177 | 473-G51 | 60% | 0.2% PVP K-30 | 20% n-propanol | |
| | | | 1% Byk-348 | 1% AMP-95 | |
| | | | 7.6% Byk-190 | in water, | |
| | | | | pH = 11.5 | |
| 178 | 473-G51 | 60% | 0.2% PVP K-30 | 30% NMP | |
| | | | 1% Byk-348 | 1% AMP-95 | |
| | | | 7.6% Byk-190 | in water, | |
| | | | | pH = 11.5 | |

Preliminary printing experiments were conducted using a Hewlett-Packard Deskjet 690 printer. Cartridge #29 was washed out with water/isopropanol/propyleneglycol (60:30:10) and then rinsed with appropriate sample solution. One milliliter of ink was placed into the internal filter zone of the cartridge and vacuumed via nozzles. Next, the printhead was refilled with 1-2 ml of ink, and printing on paper or polyimide (“Capton”) was carried out (standard table 5×50, line thickness 0.5 mm). Printed patterns were air-dried.

In general, printed patterns were obtained with several formulations, although after printing about 5-10 pages, a malfunction was observed (either clogging, flow, or wetting problem). The inks described in Examples 176 and 178 yielded the best printed patterns. The inks described in Examples 173 and 174 were printed for several pages, then it was possible to partially restore the print head by a short sonication.

### Examples 179-182

Additional compositions were prepared and tested as described above. The formulations and their properties are listed in Table 7.

TABLE 7

| | | Powder | | | | | | |
|---|---|---|---|---|---|---|---|---|
| | | size | | | | | | Surface |
| | | (D90) | Metal | | Resistivity | Sintering | Viscosity | Tension |
| Example | Metal | (μm) | Wt. % | Solvent | (μΩ cm) | Conditions | (cPs) | (dyne/cm) |
| 179 | Ag/Cu | 60 | 30 | Butanol | 20 | 300° C., 30 min. | 8 | |
| 180 | Ag/Cu | 60 | 51 | Propyl | 23 | 300° C., 30 min. | 3.5 | |
| | | | | acetate | | | | |
| 181 | Ag/Cu | 60 | 60 | BEA | 10 | 300° C., 30 min. | 10 | 25-28 |
| 182 | Ag/Cu | 60 | 60 | Water/NMP | 10 | 300° C., 30 min. | 12 | 45-50 |

A number of embodiments of the invention have been described. Nevertheless, it will be understood that various modifications may be made without departing from the spirit and scope of the invention. Accordingly, other embodiments are within the scope of the following claims.

What is claimed is:

1. A composition comprising 1-70% by weight of a nano metal powder dispersed in a liquid carrier, wherein the composition has a viscosity no greater than about 200 cP at ink jet printing temperatures and is ink jet printable.

2. A composition according to claim 1 comprising 10-60% by weight of the nano metal powder.

3. A composition according to claim 1 comprising 20-60% by weight of the nano metal powder.

4. A composition according to claim 1 wherein the composition has a viscosity of 1-200 cP at ink jet printing temperatures.

5. A composition according to claim 1 wherein the composition has a viscosity of 1-100 cP at ink jet printing temperatures.

6. A composition according to claim 1 wherein the composition has a viscosity of 2-20 cP at ink jet printing temperatures.

7. A composition according to claim 1 comprising about 60% by weight nano metal powder and having a viscosity of about 18 cP at ink jet printing temperatures.

8. A composition according to claim 1 wherein the composition has a viscosity no greater than about 200 cP at room temperature.

9. A composition according to claim 1 wherein the composition has a viscosity of 1-200 cP at room temperature.

10. A composition according to claim 1 wherein the composition has a viscosity of 1-100 cP at room temperature.

11. A composition according to claim 1 wherein the composition has a viscosity of 2-20 cP at room temperature.

12. A composition according to claim 1 comprising about 60% by weight nano metal powder and having a viscosity of about 18 cP at room temperature.

13. A composition according to claim 1 wherein the liquid carrier comprises water and the composition has a surface tension of about 30-60 dynes/cm.

14. A composition according to claim 1 wherein the liquid carrier comprises an organic solvent and the composition has a surface tension of about 20-37 dynes/cm.

15. A composition according to claim 1 wherein the nano metal powder has an average particle size no greater than about 150 nm.

16. A composition according to claim 1 wherein the nano metal powder has an average particle size no greater than about 100 nm.

17. A composition according to claim 1 wherein the nano metal powder has an average particle size no greater than about 80 nm.

18. A composition according to claim 1 wherein the nano metal powder is prepared according to the MCP process.

19. A composition according to claim 1 or 18 wherein the nano metal powder comprises silver.

20. A composition according to claim 1 or 18 wherein the nano metal powder comprises a silver-copper alloy.

21. A composition according to claim 18 wherein the nano metal powder comprises non-uniform spherical particles and includes up to about 0.4% by weight aluminum.

22. A composition according to claim 1 wherein the compositions is stable against particle settling.

23. A composition according to claim 1 wherein the liquid carrier comprises (a) at least one organic solvent and (b) at least one agent selected from the group consisting of surfactants, wetting agents, rheology modifying agents, adhesion promoters, humectants, binders, and combinations thereof.

24. A composition according to claim 1 wherein the liquid carrier comprises (a) water, a water-miscible organic solvent, or combination thereof and (b) at least one agent selected from the group consisting of surfactants, wetting agents, rheology modifying agents, adhesion promoters, humectants, binders, and combinations thereof.

25. A composition according to claim 1 wherein the liquid carrier comprises (a) at least one organic solvent, (b) a curable monomer, and (c) at least one agent selected from the group consisting of surfactants, wetting agents, rheology modifying agents, adhesion promoters, humectants, binders, and combinations thereof.

26. A method comprising printing the composition of claim 1 onto a substrate using an ink jet printer.

27. A method according to claim 26 wherein the ink jet printer is a continuous ink jet printer.

28. A method according to claim 26 wherein the ink jet printer is a drop on demand ink jet printer.

29. A method according to claim 26 wherein the substrate is selected from the group consisting of paper, polymer films, textiles, plastics, glass, printed circuit boards, epoxy resins, and combinations thereof.

30. A method according to claim 26 comprising sintering the composition after applying it to the substrate.

31. A method according to claim 26 comprising treating the composition after applying it to the substrate by applying electromagnetic radiation, pressure, thermal radiation, or a combination thereof.
